(19) United States
(12) Patent Application Publication
(10) Pub. No.: US 2026/0052654 A1
(43) Pub. Date: Feb. 19, 2026

(54) INFORMATION HANDLING SYSTEM THERMALLY CONDUCTIVE RUBBERIZED FOOT

(71) Applicant: Dell Products L.P., Round Rock, TX (US)

(72) Inventors: Po-Hung Chi, Tamsui (TW); Ling-Yi Chu, New Taipei City (TW); Ting-Chang Chang, New Taipei City (TW)

(73) Assignee: Dell Products L.P., Round Rock, TX (US)

(21) Appl. No.: 18/808,748

(22) Filed: Aug. 19, 2024

(51) Int. Cl. H05K 7/20; G06F 1/20

(52) U.S. Cl. CPC H05K 7/20481; G06F 1/203

(57) ABSTRACT

A portable information handling housing has a hot spot at a surface of the housing associated with operational conditions, such as CPU thermal dissipation, and a heat conductive rubber foot that couples at the housing bottom side with a metallic portion, such as copper, that thermally interfaces with a rubberized foot having graphene and/or carbon nanotube powder to conduct thermal energy from the hot spot towards cooler portions of the housing.

### BACKGROUND OF THE INVENTION

### Field of the Invention

The present invention relates in general to the field of portable information handling systems, and more particularly to an information handling system thermally conductive rubber foot.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Portable information handling systems integrate processing components, a display and a power source in a portable housing to support mobile operations. Portable information handling systems allow end users to carry a system between meetings, during travel, and between home and office locations so that an end user has access to processing capabilities while mobile. Tablet configurations typically expose a touchscreen display on a planar housing that both outputs information as visual images and accepts inputs as touches. Convertible configurations typically include multiple separate housing portions that couple to each other so that the system converts between closed and open positions. For example, a main housing portion integrates processing components and a keyboard and rotationally couples with hinges to a lid housing portion that integrates a display. In a clamshell configuration, the lid housing portion rotates approximately ninety degrees to a raised position above the main housing portion so that an end user can type inputs while viewing the display. After usage, convertible information handling systems rotate the lid housing portion over the main housing portion to protect the keyboard and display, thus reducing the system footprint for improved storage and mobility.

Recently, portable information handling system form factors have trended toward thinner and narrower portable housings. Low form factor housings have reduced internal volume so that space and airflow to dissipate thermal energy for rejection to external the housing is limited. One difficulty with these smaller form factors is that thermal energy can tend to concentrate in parts of the housing so that hot spots with increased temperatures can occur at the housing. These hot spots can make the system housing uncomfortable to touch, resulting in a poor end user experience. Generally, hot spots tend to develop at surface areas near the processing components that generate the thermal energy, such as near the central processing unit (CPU). In particular, a bottom central portion of the housing tends to have a hotspot where the CPU couples to the motherboard. Typically, the CPU couples to a heat sink and/or heat pipe that accepts excess thermal energy and routes the excess thermal energy to a passive or active heat exchange arrangement, such as a vent that exhausts air with or without the aid of a cooling fan. Thermal energy concentrated at the CPU and the heat exchange arrangement can result in a heated lower surface that makes resting on an end user lap uncomfortable.

### SUMMARY OF THE INVENTION

Therefore, a need has arisen for a system and method which aids dissipation of thermal energy from a portable information handling system.

In accordance with the present invention, a system and method are provided which substantially reduce the disadvantages and problems associated with previous methods and systems. A heat conductive rubber foot includes thermally conductive material that conducts thermal energy from a housing hot spot to dissipate the thermal energy through the rubberized material away from the hot spot.

More specifically, a portable information handling system has a portable housing that contains processing components that cooperate to process information, such as a central processing unit that executes instructions to process information and a memory that stores the instructions and information. The processing components generate thermal energy as a by product of operations and power dissipation. The portable housing has one or more hot spot zones where thermal energy from within the housing creates an increased housing temperature. A thermally conductive rubberized foot thermally interfaces with the hot spot and conducts thermal energy away from the hot spot. In one example embodiment, a polyurethane rubberized material is mixed with graphene and nanocarbon to conduct heat and couple to a copper mount that thermally connects with the housing to conduct thermal energy.

The present invention provides a number of important technical advantages. One example of an important technical advantage is that a heat conductive thermal foot on the base of portable information handling system housing interfaces with a hot spot of the housing with a thermally-conductive material, such as copper, to transfer heat through rubber foot material away from the hot spot, such as with graphene included in the rubber foot. The thermally-conductive material may also interface with other portions of the housing to conduct heat from the hot spot to housing surfaces that have lower temperatures, such as other locations in the bottom surface that are associated with cool spots or to an upper housing cover portion. The thermally-conductive rubber dissipates heat without excessive temperatures to improve heat balance across the housing in a low form factor that helps to manage thermal conditions in the housing for a full operational range of processing capability. Slight increases of thermal energy distributed to the housing as a whole help to improve thermal rejection for improved operational capabilities with minimal housing surface temperature increases.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an exploded perspective view of a portable information handling system having a heat conductive rubber foot to dissipate excess thermal energy from hot spot zones to cool zones of the system housing;

FIG. 2 depicts a bottom view of portable information handling system having a heat conductive rubber foot;

FIG. 3 depicts a side view of an example embodiment of a heat conductive rubber foot;

FIG. 4 depicts a side view of an alternative embodiment example of a heat conductive rubber foot for dissipating thermal energy from hot spot zone;

FIG. 5 depicts a lower side sectional view of one example of a heat conductive rubber foot interfaced with a thermal source within a portable housing; and

FIG. 6 depicts a flow diagram of a process for forming a heat conductive rubber foot.

### DETAILED DESCRIPTION

A heat conductive rubber foot coupled to an information handling system housing bottom side conducts thermal energy away from hot spots of the housing. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

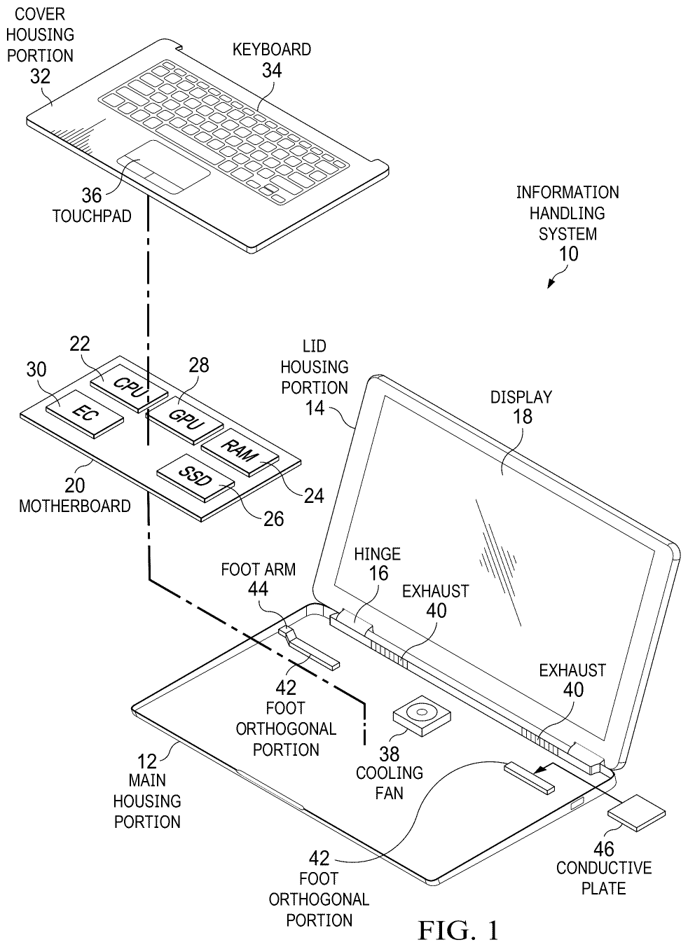

Referring now to FIG. 1, an exploded perspective view depicts a portable information handling system 10 having a heat conductive rubber foot to dissipate excess thermal energy from hot spot zones to cool zones of the system housing. In the example embodiment, portable information handling system 10 has a convertible configuration with a main portion 12 rotationally coupled to a lid portion 14 by hinges 16 to rotate between open and closed positions. In alternative embodiments, alternative housing configurations may be supported, such as tablet systems. A display 18 couples in housing lid portion 14 to present information as visual images. Processing components coupled in housing main portion 12 cooperate to process information that is presented at display 18. In the example embodiment, the processing components coupled to a motherboard 20 that includes wirelines to support communication between the processing components. A central processing unit (CPU) 22 executes instructions to process information in cooperation with a random access memory (RAM) 24 that stores the instructions and information. A solid state drive (SSD) 26 couples to motherboard 20 to provide persistent storage of information, such as an operating system and applications that execute on CPU 22. A graphics processing unit (GPU) 28 interfaces with CPU 22 to further execute instructions that generate visual images, such as by defining pixel values for presentation at display 18. An embedded controller 30 executes instructions to manage operational conditions with the system, such as power and thermal management as well as interactions with peripheral devices like a keyboard and mouse.

In the convertible configuration of the example embodiment, a housing cover portion 32 couples over housing main portion 12 to enclose the processing components. Housing cover portion 32 has a keyboard 34 that accepts key inputs coupled to the upper surface and a touchpad 36 that accepts touch inputs coupled to the upper surface. An end user interacts with information handling system 10 through the keyboard and touchpad while housing main portion 12 rests on a support surface, such as a desktop, or on the end user lap. When in use, the processing components produce thermal energy as a by product of power dissipation to perform processing tasks. A cooling fan 38 generates a cooling airflow out exhaust 40 to reject the excess thermal energy to the external environment. In various embodiments, different types of structures are used to aid in conducting thermal energy from the processing components to the external environment, such as heat sinks and heat pipes that connect with the processing components to draw thermal energy to a surface that is exposed to cooling airflow of cooling fan 38. For instance, a heat sink coupled to CPU 22 accepts excess thermal energy that is routed by a heat pipe to a metallic surface of an exhaust 40 that is directly exposed to cooling airflow of cooling fan 38. As a result, components having high thermal temperatures are kept inside of the housing and not exposed to end user touch while heated air is exhausted out the exhausts.

Although thermal management directs excess thermal energy out of the housing, the housing itself where touched by an end user has thermal constraints designed to avoid end user discomfort associated with touch of heated surfaces. Typically, hot spot zones on the housing outer surface occur near locations of heat producing processing components, such as at the location of a CPU or GPU. If the housing surface temperature gets excessive at a hot spot zone, the system typically has to slow processing clock speeds to decrease energy dissipation and reduce the housing skin temperature. Slowing processing speeds impacts the end user experience. In order to spread heat away from hot spots of the housing, a heat conductive rubber foot couples to the housing main portion to thermally interface with the housing material, such as with a direct connection to the housing material, and spreads the thermal energy through thermally conductive rubberized material to cool zones of the housing material. In the example embodiment, a heat conductive rubber foot orthogonal portion 42 connects to the bottom side of housing main portion 12 with a heat conductive metallic material, such as copper, to accept the thermal energy at a housing hot spot and conduct the thermal energy to a cool spot through rubberized foot material that embeds thermally conductive material. In one example embodiment, a foot arm 44 extends up from the orthogonal portion 42 to conduct thermal energy to cover housing portion 32 so that thermal energy from a hot spot at the bottom surface of housing main portion 12 is conducted to a cool zone at the cover housing portion. In another example embodiment, a conductive plate 46 of metallic material, such as copper, connects to the housing material and orthogonal portion 42 to aid in thermal energy transfer from the housing material to the heat conductive rubber foot. In the example embodiments, the metallic material of orthogonal portion 42 connects directly to the housing material without a direct connection to a processing component, heat sink, heat pipe or exhaust. This allows thermal transfer from housing hot spot zones to cool zones of the housing without directly transferring internal heat to the heat conductive rubber foot. In alternative embodiments, a direct connection between orthogonal portion 42 and an internal heat exchange device may be used to help conduct thermal energy from inside the housing to out of the housing as opposed to transfer of housing thermal energy across the housing.

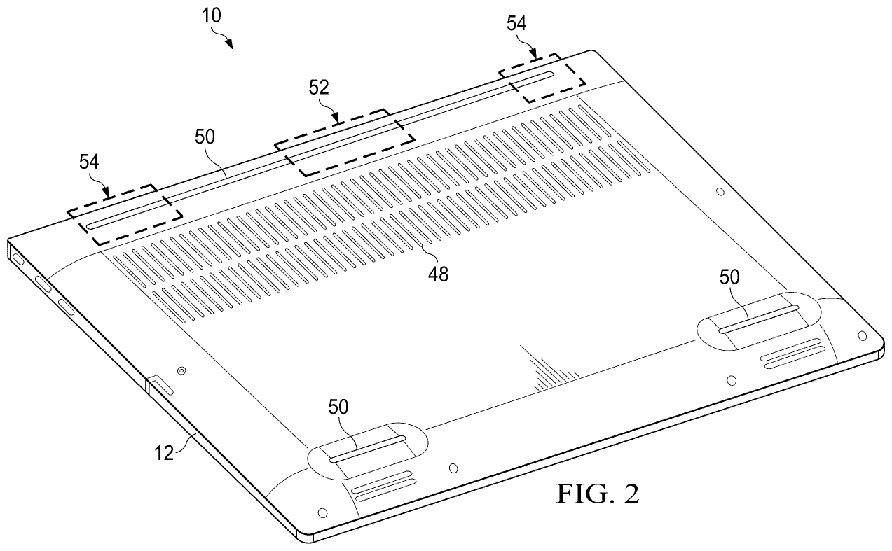

Referring now to FIG. 2, a bottom view depicts a portable information handling system 10 having a heat conductive rubber foot 50. Cooling air enters at a vent 50 to pass through the cooling fan and out the rear exhaust. During operation, a hot spot zone 52 can form that has a higher temperature than a cool spot region 54, such as at a location of a CPU or GPU. Heat conductive rubber foot conducts thermal energy from hot spot zone 52 to cool spot zone 54 through thermally conductive elements of the rubberized material. In the example embodiment, thermal energy is conducted from a central region to the outside side areas of the housing bottom. In alternative embodiments, thermal energy may be directed to any cool zone with the internal arm or by front feet that interface with thermally active areas.

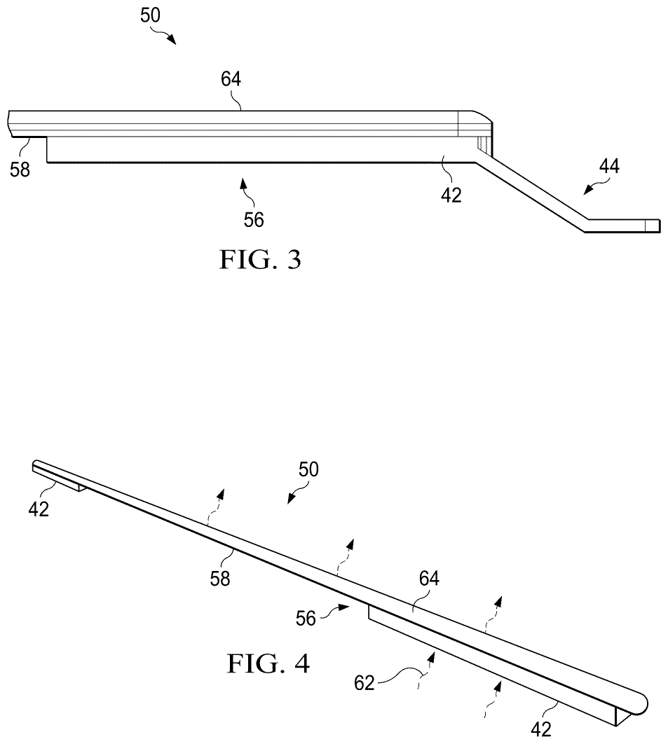

Referring now to FIG. 3, a side view depicts an example embodiment of a heat conductive rubber foot 50. In the example embodiment, a metallic mount 56 is formed with copper or a similar metal having high thermal conductivity. A rubberized material 64 couples to a planar portion 58 of mount 56 to support the weight of the system on a support surface, such as a desktop. Orthogonal portion 42 extends from planar portion 58 into the housing interior to connect with the housing material so that thermal energy is conducted from the housing material at a hot spot to the rubberized material 64. Rubberized material 64 connects to the planar portion of mount 56 by adhesive bonding or insert injection molding that embeds the mount in the rubberized material. Mount 56 has an arm 44 that extends up from orthogonal portion 42 to couple to a different part of the housing that has a cool zone, such as a cover portion. Rubberized material 64 is, for instance, a mix of graphene and carbon nanotube power with a polyurethane plastic that forms a foot shape and offers thermal conductivity to transfer thermal energy along the length of the foot and to the housing distal a hot spot.

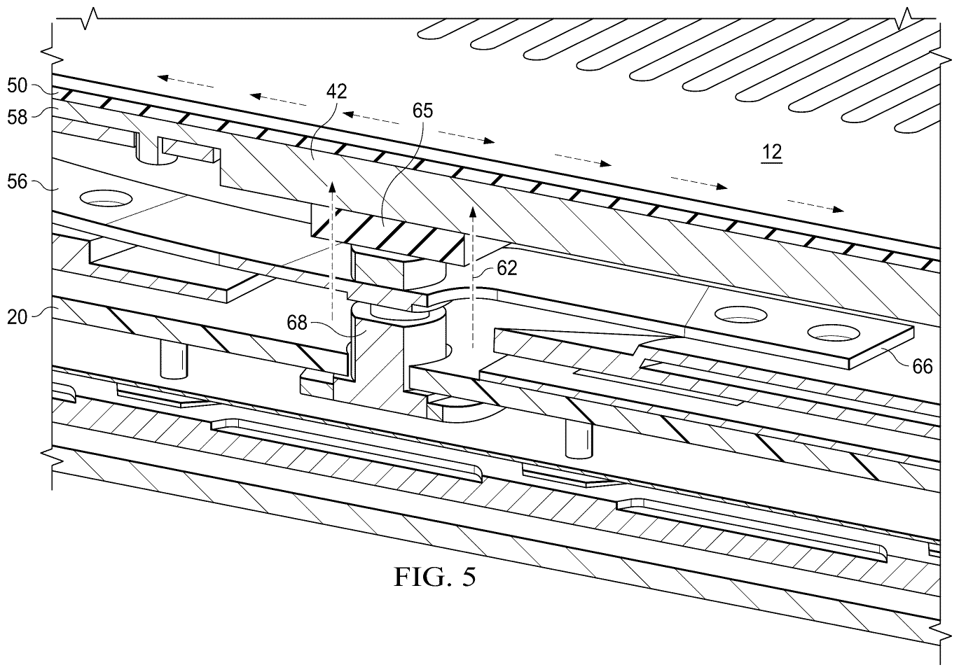

Referring now to FIG. 4, a side view depicts an alternative embodiment example of a heat conductive rubber foot for dissipating thermal energy from hot spot zone. In the example embodiment, an orthogonal portion 42 extends into the housing interior at opposite ends of mount 56 and interface with each other by a planar portion 58. Thermal energy from housing hot spot zones is conducted by a connection of the orthogonal portion to the housing at a heat source 62 and into the rubberized material 64. The thermal energy is dissipated through the rubberized material so that the bottom side of the housing has a more uniform thermal distribution. In one example embodiment, the mount connects to the housing at a hot spot zone with a first orthogonal portion and connects to the housing at a cool spot zone with a second orthogonal portion. This allows thermal energy to conduct through the rubberized material from the hot spot zone to the cool spot zone so that a more uniform housing temperature results. In various embodiments, mount 56 may be built from alternative thermally conductive materials, such as aluminum or other metals.

Referring now to FIG. 5, a lower side sectional view depicts one example of a heat conductive rubber foot 50 interfaced with a thermal source 62 within a portable housing 12. In the example embodiment, the thermal source is a motherboard 20 coupling device 68 that secures with metal arms 66 extending between the motherboard and housing. A thermal pad 65 couples to the coupling device 68 to conduct thermal energy from the coupling device to mount 56 to orthogonal portion 42. Thermal energy transfers from orthogonal portion 42 to planar portion 58 and the rubberized material. In the example embodiment, the hot spot zone results from the greater thermal conductivity of the metal motherboard coupling device so that direct contact with the motherboard coupling device tends to transfer thermal energy and thereby minimize the hot spot temperature differential. In one example embodiment, the heat conductive rubber foot decreases housing thermal temperatures at the hot spot zone by five degrees Celsius from 57 degrees to 50 degrees.

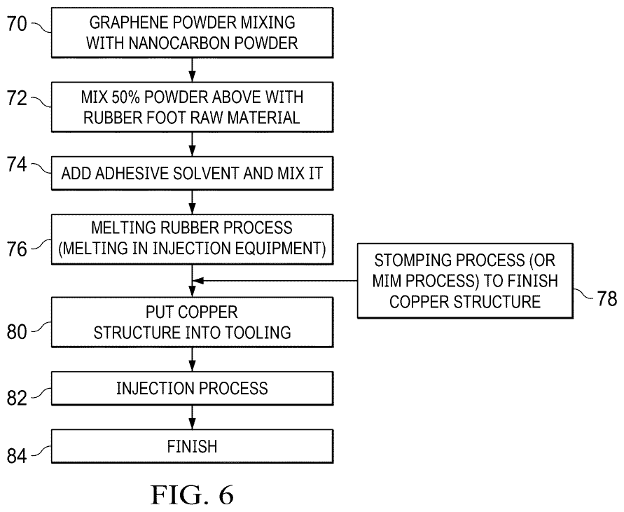

Referring now to FIG. 6, a flow diagram depicts a process for forming a heat conductive rubber foot. The process starts at step 70 with graphene powder mixing with nanocarbon powder. In alternative embodiments, other thermally conductive materials may be selected. At step 72, a mixture of half thermally conductive material and half polyurethane rubber is mixed and prepared for injection molding. At step 74 the mixture of thermally conductive material and rubber material have an adhesive solvent added and at step 76 the mixture is heated to melt in the injection molding equipment. At step 78, a stomping process or metal injection molding process is performed to form the mount of copper. At step 80, the copper mount is placed into the injection molding tooling. At step 82, the injection molding process is performed to embed the rubberized material with thermally conductive material on the copper mount. At step 84 the process finishes with the heat conductive rubber foot formed to conduct heat through the metal mount from the housing material and down the rubber material for dissipation across the housing surface.

Although the present invention has been described in detail, it should be understood that various changes, substitutions and alterations can be made hereto without departing from the spirit and scope of the invention as defined by the appended claims.

What is claimed is:

1. An information handling system comprising:
a portable housing;
a processor coupled in the housing and operable to execute instructions to process information;
a memory coupled in the housing and interfaced with the processor to store the instructions and information; and
a foot coupled to a bottom side of the housing with a rubberized portion extending out to support the housing in a raised position above a surface, the foot having a thermally conductive material integrated in the rubberized portion, the rubberized portion thermally interfaced with a metallic mount, the metallic mount conducting thermal energy from the housing to the rubberized portion.

2. The information handling system of claim 1 further comprising:
a graphene thermally conductive material integrated in the rubberize portion; and
a copper metallic mount coupled to the rubberized portion.

3. The information handling system of claim 2 wherein the rubberized portion comprises polyurethane rubber injection molded with graphene to the copper metallic mount.

4. The information handling system of claim 3 wherein the polyurethane rubber is further injection molded with carbon nanotube power.

5. The information handling system of claim 1 wherein the metallic mount thermally interfaces with the housing bottom side at a hot spot portion to conduct thermal energy from the hot spot portion to the rubberized portion.

6. The information handling system of claim 5 wherein the metallic mount has an arm that extends upward from the rubberized portion into an interior of the housing to thermally couple with the housing distal the hot spot portion.

7. The information handling system of claim 1 further comprising first and second of the foot coupled to opposite sides of the housing bottom surface.

8. The information handling system of claim 1 wherein the metallic mount comprises:
a planar portion parallel with the housing bottom surface; and
first and second orthogonal portions extending into the housing at opposite sides of the planar portion.

9. The information handling system of claim 8 wherein the rubberized portion extends between the first and second orthogonal portions across the planar portion.

10. A method for managing thermal conditions at an information handling system housing surface, the method comprising:
thermally interfacing a metallic portion of a foot with the housing surface at a hot spot of the housing surface;
thermally interfacing a rubberized portion of the foot with the metallic portion; and
conducting thermal energy through the rubberized portion away from the hot spot.

11. The method of claim 10 further comprising:
forming the foot with insertion injection molding of polyurethane rubber onto a copper metallic portion; and
mixing graphene with the polyurethane rubber.

12. The method of claim 11 further comprising mixing carbon nanotube powder with the polyurethane rubber.

13. The method of claim 10 further comprising:
extending the metallic portion as an arm up into an interior of the housing; and
thermally interfacing the arm with the housing distal the hot spot of the housing surface.

14. The method of claim 10 further comprising:
forming the metallic portion to have a parallel portion embedded in the rubberized material and an orthogonal portion extending out from the rubberized material; and
coupling the orthogonal portion to the housing at the hot spot.

15. The method of claim 10 further comprising:
forming the metallic portion to have a parallel portion embedded in the rubberized material and first and second orthogonal portions extending out from the rubberized material; and
coupling the first and second orthogonal portions to first and second hot spots of the housing.

16. The method of claim 15 further comprising coupling the foot to the housing to direct the conducting thermal energy to opposing sides of the housing.

17. An information handling system housing comprising:
a bottom side having a hot spot; and
a foot coupled to the bottom side of the housing with a rubberized portion extending out to support the housing in a raised position above a surface, the foot having a thermally conductive material integrated in the rubberized portion, the rubberized portion thermally interfaced with a metallic mount, the metallic mount conducting thermal energy from the hot spot through the rubberized portion.

18. The information handling system housing of claim 17 wherein:
the rubberized material comprises rubber polyurethane, graphene and carbon nanotube; and
the metallic mount comprises copper.

19. The information handling system housing of claim 18 wherein the metallic mount thermally interfaces with the housing bottom side at the hot spot to conduct thermal energy from the hot spot to the rubberized portion and the metallic mount extends into an interior of the housing to couple to the housing to conduct thermal energy from the hot spot.

20. The information handling system housing of claim 19 wherein the metallic mount has a parallel portion that embeds in the rubberized portion and an orthogonal portion that extends out of the rubberized portion.
